(19) United States
(12) Patent Application Publication
(10) Pub. No.: US 2019/0101714 A1
(43) Pub. Date: Apr. 4, 2019

(54) OPTICAL MODULE

(71) Applicant: FUJITSU COMPONENT LIMITED, Tokyo (JP)

(72) Inventors: Shigemi Kurashima, Tokyo (JP); Mitsuki Kanda, Tokyo (JP); Takatoshi Yagisawa, Tokyo (JP); Masahiro Yanagi, Tokyo (JP)

(21) Appl. No.: 16/145,405

(22) Filed: Sep. 28, 2018

(30) Foreign Application Priority Data
Oct. 2, 2017 (JP) 2017-192337

(51) Int. Cl. G02B 6/42; H05K 9/00

(52) U.S. Cl. CPC G02B 6/4277; G02B 6/4281; G02B 6/4246; H05K 9/0058; G02B 6/4295

(57) ABSTRACT

An optical module includes a board, a light emitter disposed on the board, a light receiver disposed on the board, and at least one radio-wave absorber disposed between the light emitter and the light receiver.

### CROSS-REFERENCE TO RELATED APPLICATION

The present application is based on and claims priority to Japanese Patent Application No. 2017-192337, filed on Oct. 2, 2017, the entire contents of which are incorporated herein by reference.

### BACKGROUND OF THE INVENTION

### 1. Field of the Invention

An aspect of this disclosure relates to an optical module.

### 2. Description of the Related Art

Electric cables made of, for example, copper have been used for communications performed by supercomputers and high-end servers via high -speed interfaces. However, optical communication is becoming popular to achieve high-speed signal transmission and to increase the transmission distance.

Next generation interfaces with a long transmission distance of dozens of meters employ optical communication technologies, and use optical modules to connect optical cables to servers and convert electric signals into optical signals. An optical module converts an optical signal from an optical cable into an electric signal, outputs the electric signal to a server, converts an electric signal from the server into an optical signal, and outputs the optical signal to the optical cable.

An optical module includes a light emitter for converting an electric signal into an optical signal, a light receiver for converting an optical signal into an electric signal, a driving integrated circuit (IC) for driving the light emitter, and a trans-impedance amplifier (TIA) for converting an electric current into a voltage. The light emitter, the light receiver, the driving IC, and the TIA are mounted on a board. The light emitter and the light receiver are connected to a ferrule such as a lens ferrule via an optical waveguide (see, for example, Japanese Laid-Open Patent Publication No. 2013-069883 and Japanese Laid-Open Patent Publication No. 2014-085513).

### SUMMARY OF THE INVENTION

In an aspect of this disclosure, there is provided an optical module that includes a board, a light emitter disposed on the board, a light receiver disposed on the board, and at least one radio-wave absorber disposed between the light emitter and the light receiver.

### BRIEF DESCRIPTION OF THE DRAWINGS

FIG. 1 is an exploded perspective view of an optical module;

FIG. 2 is a drawing illustrating a configuration of an optical module;

FIG. 3 is a graph illustrating a frequency characteristic of an electromagnetic wave leaking from an optical module and measured while the optical module is powered off;

FIG. 4 is a graph illustrating a frequency characteristic of an electromagnetic wave leaking from an optical module and measured while the optical module is powered on;

FIG. 5 is a drawing illustrating an arrangement of a light emitter and a light receiver of an optical module;

FIG. 6 is a drawing illustrating an optical module according to a first embodiment;

FIG. 7 is a drawing illustrating a variation of the optical module of the first embodiment;

FIG. 8 is a drawing illustrating a radio -wave absorber;

FIGS. 9A through 9C are drawings illustrating simulation models;

FIG. 10 is a graph illustrating transmission characteristics of simulation models;

FIG. 11 is a drawing illustrating an optical module according to a second embodiment;

FIG. 12 is a drawing illustrating a first variation of the optical module of the second embodiment; and

FIG. 13 is a drawing illustrating a second variation of the optical module of the second embodiment.

### DESCRIPTION OF EMBODIMENTS

With an optical module using a high -frequency electric signal, an electromagnetic wave that becomes noise may be generated when the optical module is actuated, and the reception sensitivity of the optical module may decrease.

Accordingly, there is a demand for an optical module whose reception sensitivity does not decrease when the optical module is actuated. Also, if the entire surface of an optical module is covered by a radio-wave absorbing sheet, heat generated in, for example, a driving IC cannot be readily released.

An aspect of this disclosure makes it possible to suppress a decrease in the reception sensitivity of an actuated optical module.

Embodiments of the present invention are described below with reference to the accompanying drawings. Throughout the drawings, the same reference number is assigned to the same component, and repeated descriptions of the same component are omitted.

### First Embodiment

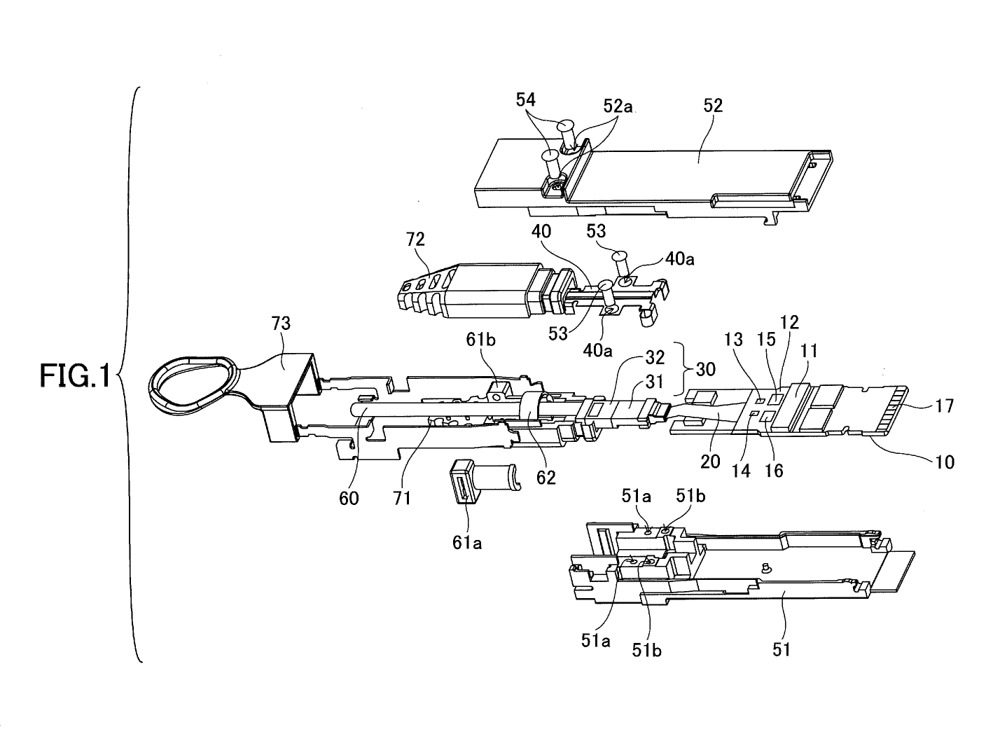

First, an optical module is described with reference to FIG. 1. FIG. 1 is an exploded perspective view of the optical module.

The optical module of FIG. 1 includes a circuit board (board) 10, an optical waveguide 20, an optical connector 30, and a clip 40 that are housed in a housing formed by a lower housing 51 and an upper housing 52. An optical cable 60 is connected to the optical module. A part of the optical cable 60 is covered by the housing.

The board 10 includes a flexible printed -circuit (FPC) connector 11 to which an FPC 12 is connected. The FPC 12 includes a light emitter 13 such as a vertical cavity surface emitting laser (VCSEL) that converts an electric signal into an optical signal and outputs the optical signal, a light receiver 14 such as a photodiode that converts an optical signal into an electric signal, a driving IC 15 for driving the light emitter 13, and a TIA 16 that is connected to the light receiver 14 and converts an electric current output from the light receiver 14 into a voltage. The board 10 includes a terminal 17 for connection with an external device. In the present application, the driving IC 15 may be referred to as a “driving circuit”, and the TIA 16 may be referred to as a “conversion circuit”.

The optical waveguide 20 is formed like a flexible sheet, and includes multiple cores surrounded by clads. Light entering the optical waveguide 20 propagates through the cores. One end of the optical waveguide 20 is connected to the board 10. The optical waveguide 20 transmits light entering the light receiver 14 and light emitted from the light emitter 13.

The optical connector 30 includes a lens ferrule 31 and an MT ferrule 32 that are connected to each other and held together by the clip 40.

The optical waveguide 20 is connected to the lens ferrule 31. Screw holes 40a formed in the clip 40 are aligned with screw holes 51a of the lower housing 51, and the clip 40 is screwed to the lower housing 51 with screws 53. With the clip 40 screwed to the lower housing 51, the optical connector 30 is fixed to the lower housing 51.

Sleeves 61a and 61b are fixed by a crimp ring 62 to the optical cable 60. A portion of the optical cable 60 to which the sleeves 61a and 61b are fixed is covered by upper and lower cable boots 71 and 72, and a pull-tab/latch 73 is attached to the housing.

The optical connector 30 is fixed via the clip 40 to the lower housing 51, the upper housing 52 is placed on the lower housing 51 on which the board 10 is placed, and screws 54 are screwed into screw holes 52a of the upper housing 52 and screw holes 51b of the lower housing 51 to fix the upper housing 52 to the lower housing 51.

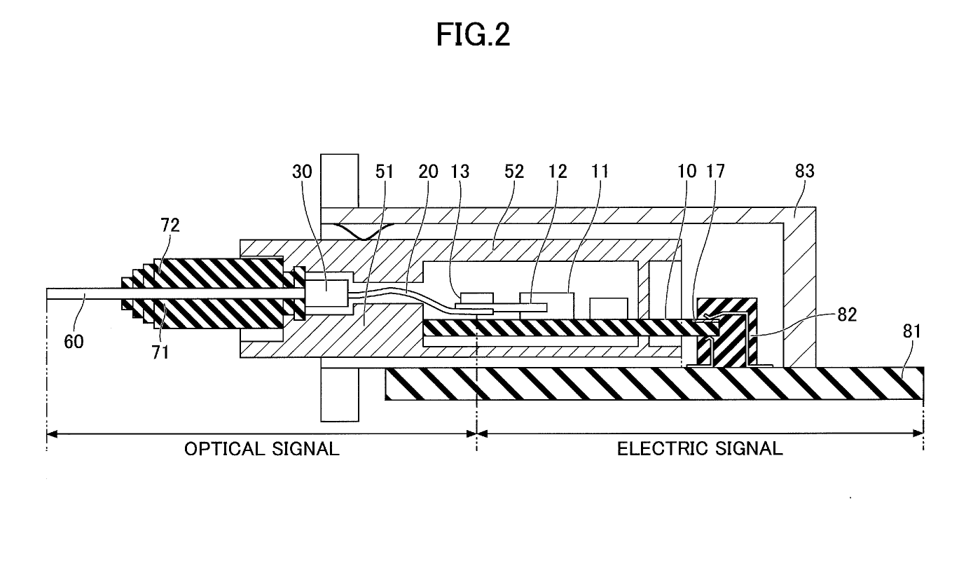

As illustrated in FIG. 2, the terminal 17 is inserted into a connector 82 of a board 81 of an external device, and the optical module is connected to the connector 82. A cage 83 is provided to cover the optical module connected to the connector 82. The lower housing 51, the upper housing 52, and the cage 83 are formed of a metal.

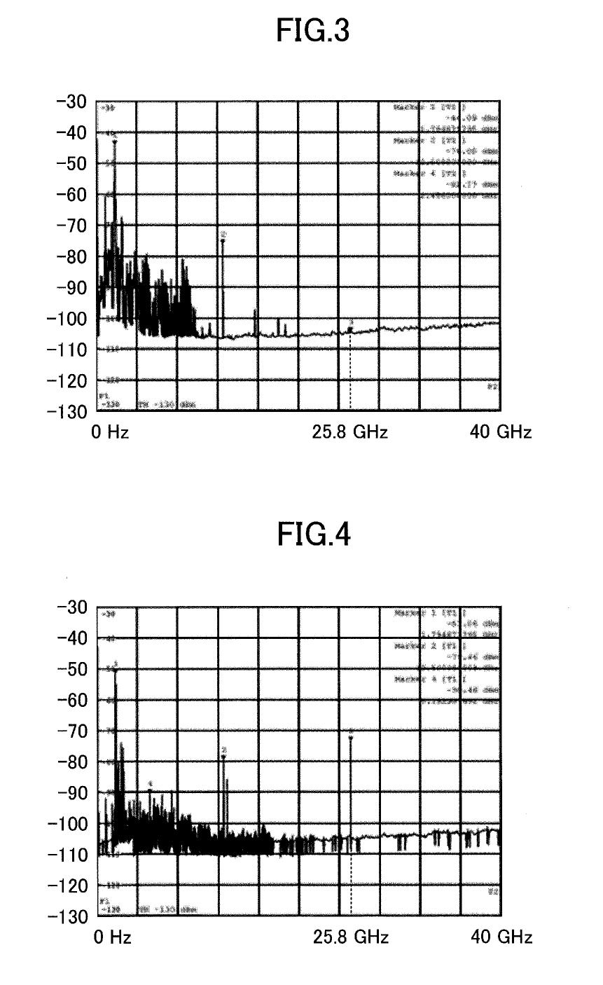

When the optical module is actuated, an electromagnetic wave is generated. FIGS. 3 and 4 illustrate frequency characteristics that are obtained by measuring electromagnetic waves leaking from the optical module using an antenna disposed near an end of the optical module closer to the optical cable 60. FIG. 3 illustrates a frequency characteristic of an electromagnetic wave measured while the optical module is powered off, and FIG. 4 illustrates a frequency characteristic of an electromagnetic wave measured while the optical module is powered on. Comparing FIGS. 3 and 4, when the optical module is powered on, noise is generated at a frequency of about 25.8 GHz. The intensity of the electromagnetic wave with the frequency of about 25.8 GHz is −73.5 dBm. Here, the optical module uses a frequency of about 12.5 GHz.

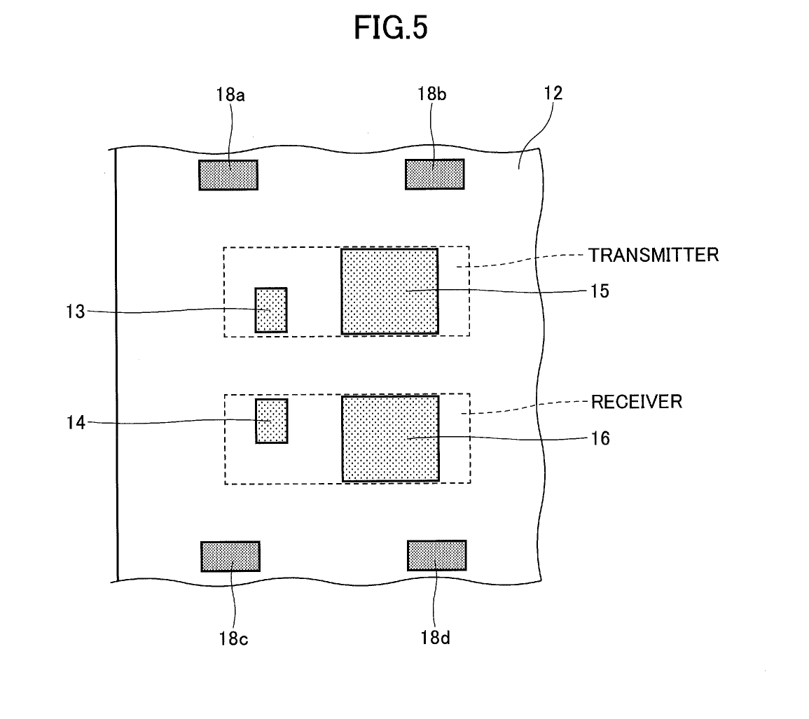

Thus, an electromagnetic wave may be generated as noise when the optical module is actuated, and the electromagnetic wave may reduce the reception sensitivity of the optical module. As illustrated in FIG. 5, the FPC 12 includes the light emitter 13, the light receiver 14, the driving IC 15, and the TIA 16. Also, multiple capacitors 18a, 18b, 18c, and 18d are provided around these components. The light emitter 13 and the driving IC 15 form a transmitter of the optical engine, and the light receiver 14 and the TIA 16 form a receiver of the optical engine. Because a comparatively-large current flows through the transmitter to drive the light emitter 13, electromagnetic waves are generated at the light emitter 13 and the driving IC 15. The generated electromagnetic waves influence the light receiver 14 and the TIA 16 disposed near the light emitter 13 and the driving IC 15 and cause the reception sensitivity to decrease.

### <Optical Module>

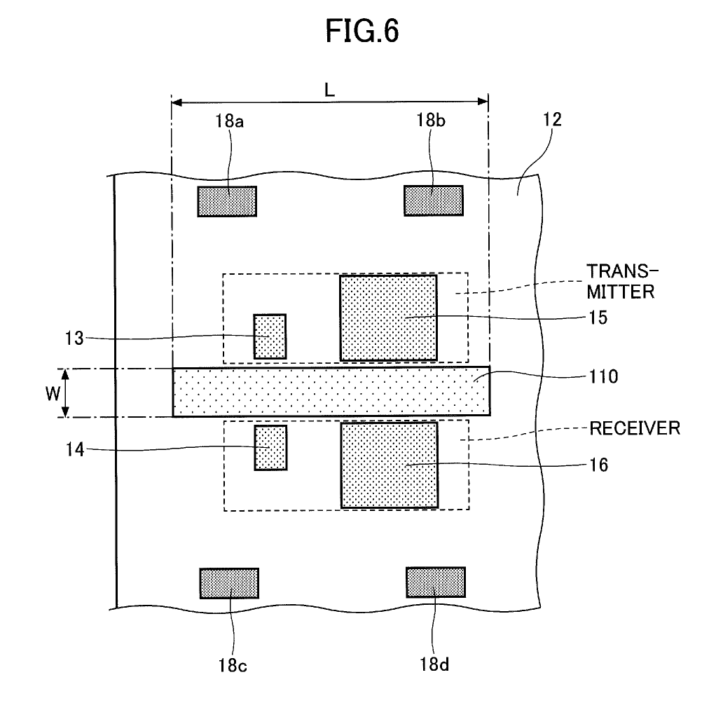

Next, an optical module according to a first embodiment is described. As illustrated in FIG. 6, the optical module of the first embodiment includes a radio-wave absorber 110 disposed between the transmitter and the receiver. The absorber 110 is formed of a material such as ferrite that absorbs electromagnetic waves, and is attached using, for example, a double-sided tape to an area on the FPC 12 between the transmitter and the receiver. The absorber 110 is preferably formed of a material whose electromagnetic-wave absorption rate increases as the frequency of the electromagnetic wave becomes closer to 25 GHz. For example, BRS-1 of Emerson & Cuming Microwave Products may be used for the absorber 110.

Each of the light emitter 13 and the light receiver 14 has a size of 1.0 mm×0.4 mm, and each of the driving IC 15 and the TIA 16 has a shape of a square each side of which has a length of 2.2 mm. Each of the capacitors 18a, 18b, 18c, and 18d has a size of 1.0 mm×0.5 mm or 0.6 mm×0.3 mm. The absorber 110 has a width W of 0.65 mm and a length L of 7 to 8 mm.

The absorber 110 disposed between the transmitter and the receiver absorbs and decreases the intensity of electromagnetic waves generated at the light emitter 13 and the driving IC 15, and may reduce the influence of the electromagnetic waves on the light receiver 14 and the TIA 16.

As illustrated in FIG. 8, the absorber 110 includes a radio-wave absorbing sheet 111 and a double-sided tape 112 attached to the absorbing sheet 111. A release tape 113 is attached to a side of the tape 112 that is opposite the side contacting the absorbing sheet 111. The absorber 110 is attached to the FPC 12 by removing the release tape 113 and attaching the tape 112 to the FPC 12.

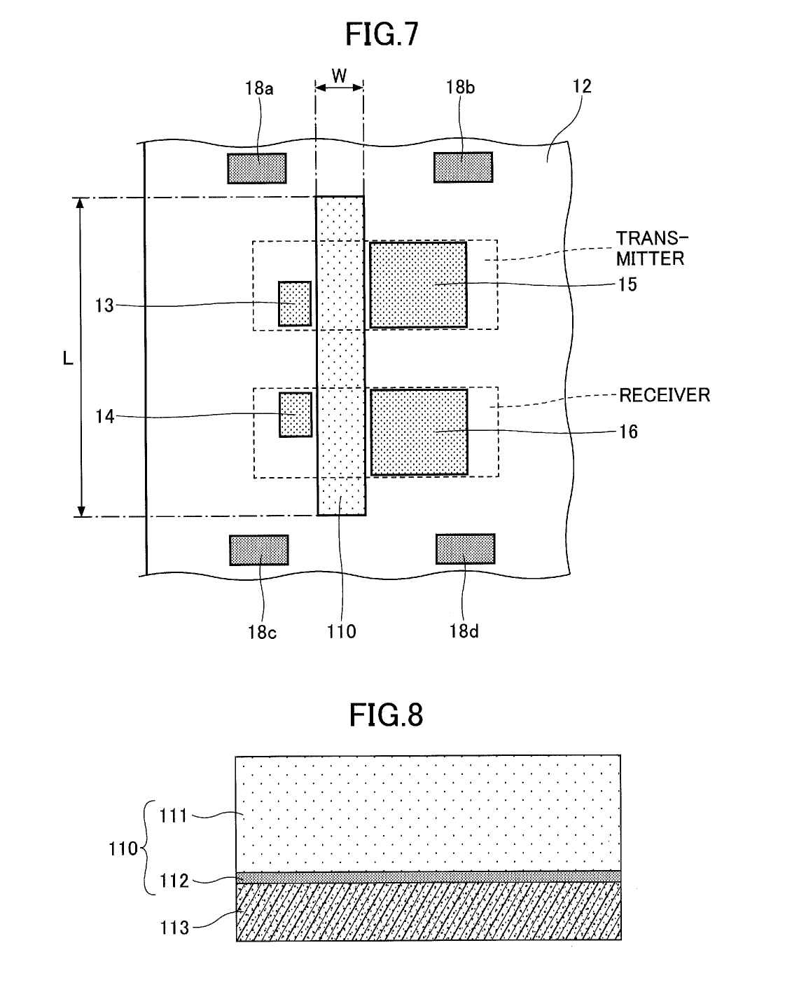

As illustrated in FIG. 7, the optical module of the first embodiment may also have the absorber 110 disposed between a combination of the light emitter 13 and the light receiver 14 and a combination of the driving IC 15 and the TIA 16.

### Second Embodiment

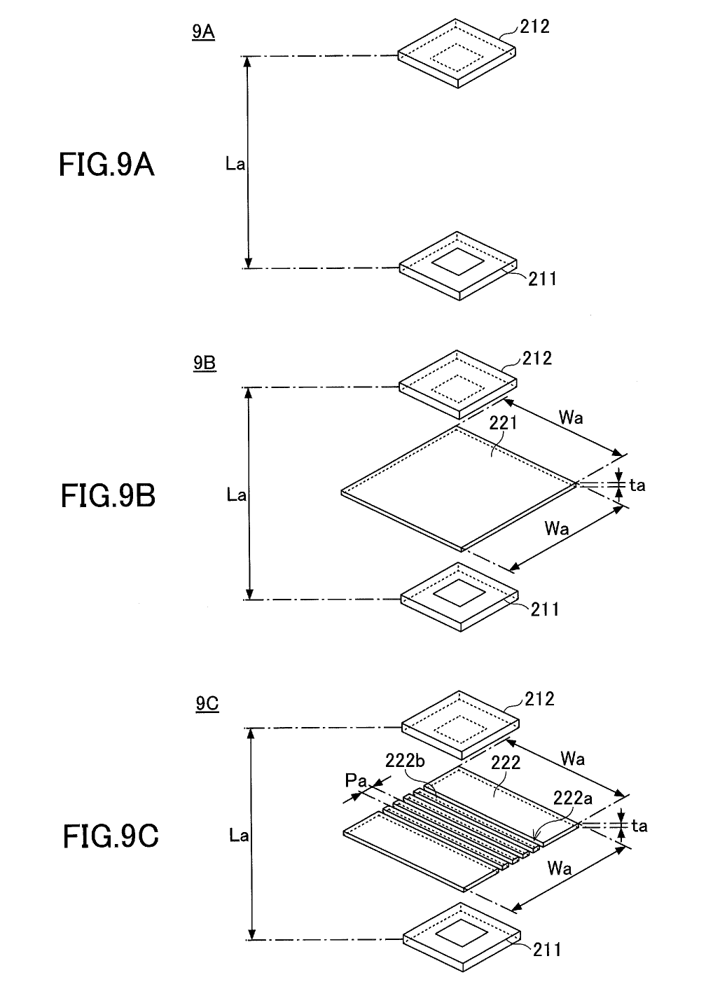

Next, a second embodiment is described. An optical module of the second embodiment includes multiple radio-wave absorbers. Before describing the second embodiment, simulations conducted using two planar antennas called patch antennas are described. Patch antennas with a resonance frequency of 25 GHz, which corresponds to the noise frequency, are used for the simulations. In the simulations, as illustrated in FIGS. 9A through 9C, a radio wave emitted by an antenna 211 is received by an antenna 212, and a transmission characteristic S21 is obtained based on the power of the radio wave emitted by the antenna 211 and the power of the radio wave received by the antenna 212.

In the simulations, the transmission characteristic S21 is calculated for each of models 9A through 9C. FIG. 9A illustrates the model 9A where no radio-wave absorbing sheet is provided between the antenna 211 and the antenna 212, FIG. 9B illustrates the model 9B where a radio-wave absorbing sheet 221 is provided between the antenna 211 and the antenna 212, and FIG. 9C illustrates the model 9C where a radio-wave absorbing sheet 222 including slits is provided between the antenna 211 and the antenna 212. A distance La between the antenna 211 and the antenna 212 is 30 mm. The absorbing sheet 221 in FIG. 9B has a thickness ta of 0.5 mm and has a square shape each side of which has a width Wa of 30 mm. The absorbing sheet 222 in FIG. 9C has a thickness ta of 0.5 mm and has a square shape each side of which has a width Wa of 30 mm. Five slits 222a with a width of 0.5 mm are formed in the middle of the absorbing sheet 222. A pitch Pa between the slits 222a is 3 mm, and four strip areas 222b are defined by the slits 222a in the absorbing sheet 222. An electromagnetic wave with a frequency of 25 GHz has a wavelength λ of about 12 mm, and the 3 mm pitch Pa corresponds to about λ/4. With the pitch Pa corresponding to about λ/4 (where λ indicates a wavelength at the noise frequency), the strip areas 222b are arranged at intervals corresponding to the peaks of the noise amplitude. The pitch Pa may be less than or equal to λ/4. This configuration is supposed to increase the radio-wave absorption effect of the absorbing sheet 222.

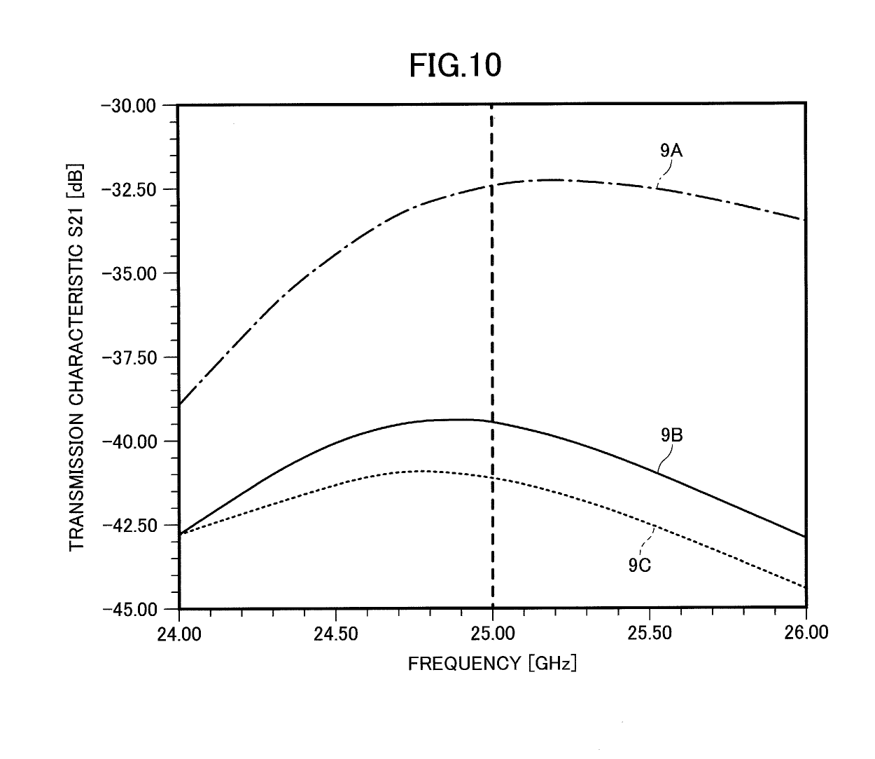

FIG. 10 is a graph illustrating transmission characteristics S21 of the models 9A, 9B, and 9C. As illustrated in FIG. 10, at 25 GHz, the transmission characteristic S21 of the model 9A, where no radio-wave absorbing sheet is provided between the antenna 211 and the antenna 212, is −32.5 dB; the transmission characteristic S21 of the model 9B, where the absorbing sheet 221 is provided between the antenna 211 and the antenna 212, is −39.5 dB; and the transmission characteristic S21 of the model 9C, where the absorbing sheet 222 including slits is provided between the antenna 211 and the antenna 212, is −41.1 dB. Table 1 indicates the results of the simulations.

TABLE 1

| | TRANSMISSION | | |
|---|---|---|---|
| | CHARACTERISTIC S21 [dB] | | |
| | 9A | 9B | 9C |
| TRANSMISSION | −32.5 dB | −39.5 dB | −41.1 dB |
| CHARACTERISTIC S21 | | | |
| BETWEEN ANTENNAS | | | |
| AT 25 GHz | | | |
| DIFFERENCE FROM 9A | | 7.0 dB | 8.6 dB |

As indicated by Table 1, providing the absorbing sheet 221 between the antenna 211 and the antenna 212 as in the model 9B decreases the transmission characteristic S21 at 25 GHz by 7 dB compared with the model 9A. This indicates that the electromagnetic wave is absorbed by the absorbing sheet 221. Also, using the absorbing sheet 222 including slits as in the model 9C decreases the transmission characteristic S21 at 25 GHz by 8.6 dB compared with the model 9A. Thus, slits formed in a radio-wave absorbing sheet at a predetermined pitch may decrease the transmission characteristic S21 by 1.6 dB compared with the model 9B where the absorbing sheet 221 with no slit is used.

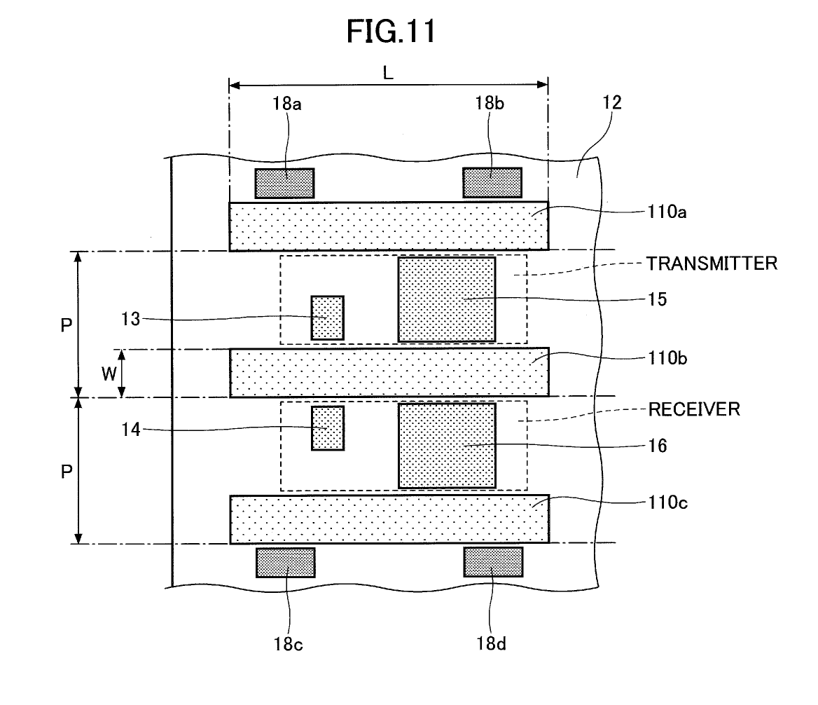

The optical module of the second embodiment is obtained based on the results of the above research, and includes multiple radio-wave absorbers. In the example of FIG. 11, the optical module includes three strip-shaped radio-wave absorbers 110a, 110b, and 110c. Similarly to the absorber 110 of the first embodiment, the absorbers 110a, 110b, and 110c have a width W of 0.65 mm and a length L of 7 to 8 mm, and are arranged on the FPC 12 at a pitch P of about 3 mm in the width direction of the absorbers 110a, 110b, and 110c.

In the second embodiment, the wave absorber 110b is disposed between the transmitter and the receiver, the absorber 110a is disposed between the transmitter and the capacitors 18a and 18b, and the absorber 110c is disposed between the receiver and the capacitors 18c and 18d. Thus, the transmitter is disposed between the absorber 110a and the absorber 110b, and the receiver is disposed between the absorber 110b and the absorber 110c.

A measured reception sensitivity of the optical module of FIG. 5 is −5.3 dB, and a measured reception sensitivity of the optical module of the second embodiment is −6.1 dB. Thus, the reception sensitivity has been improved by 0.8 dB.

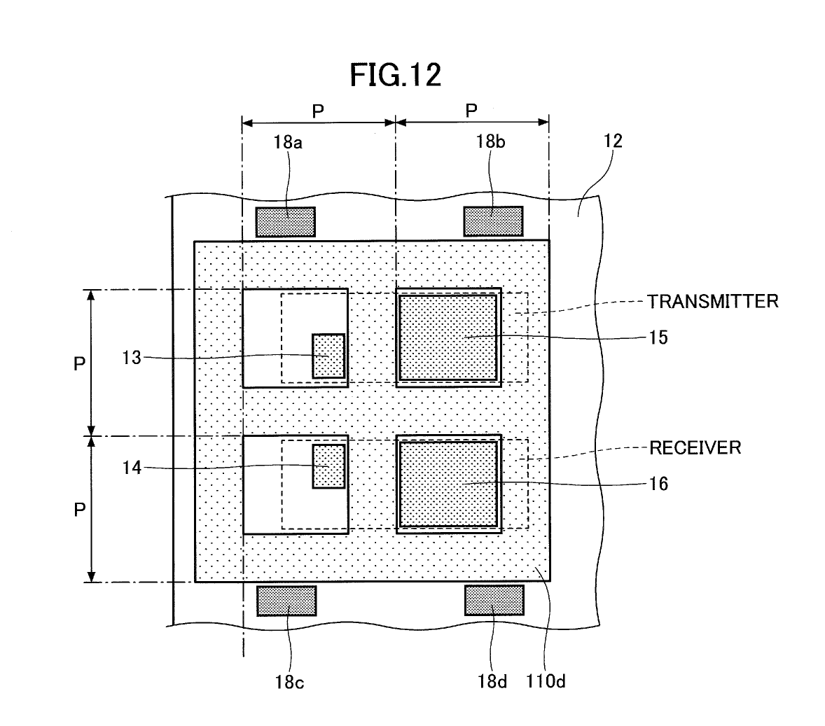

In the second embodiment, as illustrated in FIG. 12, a radio-wave absorber 110d shaped like a matrix that is formed by vertical and horizontal radio-wave absorbers may also be used. With this configuration, the absorber 110d exists between the light emitter 13 and the light receiver 14, between the driving IC 15 and the TIA 16, between the light emitter 13 and the driving IC 15, and between the light receiver 14 and the TIA 16.

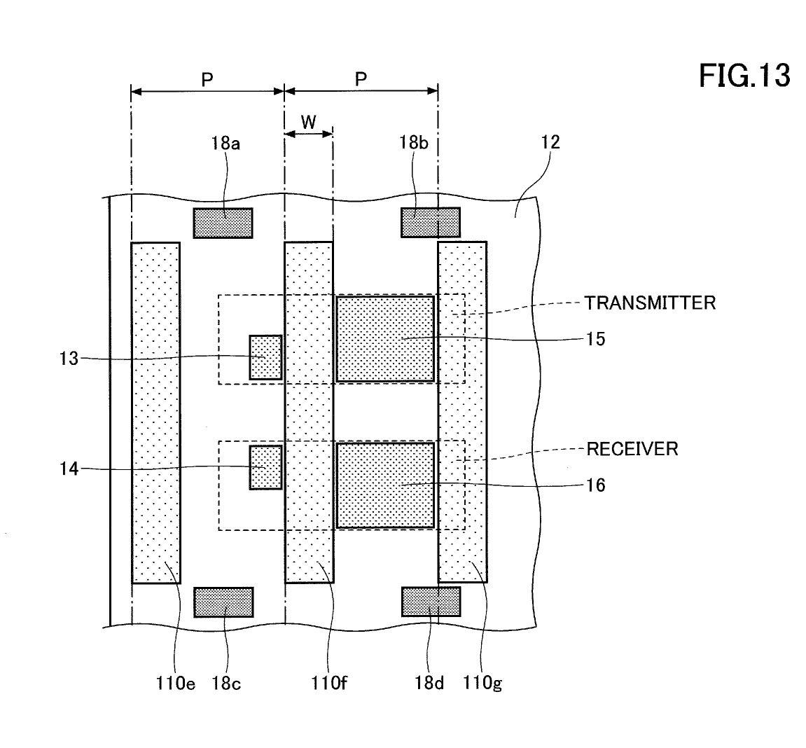

Also in the second embodiment, as illustrated in FIG. 13, three absorbers 110e, 110f, and 110g may be provided such that the light emitter 13 and the light receiver 14 are disposed between the absorber 110e and the absorber 110f, and the driving IC 15 and the TIA 16 are disposed between the absorber 110f and the absorber 110g. This configuration can reduce cross talks, which are caused by the radio-wave absorbing sheet, between adjacent channels in each of the transmitter and the receiver.

Configurations of the optical module of the second embodiment other than those described above are substantially the same as those described in the first embodiment.

Optical modules according to embodiments of the present invention are described above. However, the present invention is not limited to the specifically disclosed embodiments, and variations and modifications may be made without departing from the scope of the present invention.

What is claimed is:

1. An optical module, comprising:
a board;
a light emitter disposed on the board;
a light receiver disposed on the board; and
at least one radio-wave absorber disposed between the light emitter and the light receiver.

2. The optical module as claimed in claim 1, wherein the at least one radio-wave absorber comprises a plurality of radio-wave absorbers.

3. The optical module as claimed in claim 2, wherein the radio-wave absorbers are arranged at a pitch of less than or equal to λ/4 where λ indicates a wavelength of an electromagnetic wave generated in the optical module.

4. The optical module as claimed in claim 1, further comprising:
an optical waveguide connected to the board and configured to transmit light entering the light receiver and light emitted from the light emitter;
an optical connector connected to the optical waveguide;
an optical cable connected to the optical connector; and
a housing that houses at least the board, the optical waveguide, and the optical connector.

5. An optical module, comprising:
a board;
a light emitter disposed on the board;
a light receiver disposed on the board;
a driving circuit configured to drive the light emitter;
a conversion circuit connected to the light receiver and configured to convert an electric current into a voltage; and
at least one radio-wave absorber that is disposed in at least one of
a position between a combination of the light emitter and the driving circuit and a combination of the light receiver and the conversion circuit, and
a position between a combination of the light emitter and the light receiver and a combination of the driving circuit and the conversion circuit.
